(19) United States
(12) Patent Application Publication
(10) Pub. No.: US 2026/0156879 A1
(43) Pub. Date: Jun. 4, 2026

(54) SELF ALIGNED BACKSIDE CAP

(71) Applicant: INTERNATIONAL BUSINESS MACHINES CORPORATION, Armonk, NY (US)

(72) Inventors: Yasir Sulehria, Niskayuna, NY (US); Ruilong Xie, Niskayuna, NY (US); Jeonghyun Hwang, Ithaca, NY (US); Mahender Kumar, Clifton Park, NY (US); Shogo Mochizuki, Mechanicville, NY (US); Kisik Choi, Watervliet, NY (US)

(21) Appl. No.: 18/968,507

(22) Filed: Dec. 4, 2024

(51) Int. Cl. H10D 62/10; H01L 23/528; H10D 30/01; H10D 30/43; H10D 30/67; H10D 62/13; H10D 64/01; H10D 84/01; H10D 84/83

(52) U.S. Cl. CPC H10D 62/121; H10D 30/014; H10D 30/43; H10D 30/6735; H10D 30/6757; H10D 62/151; H10D 64/018; H10D 84/013; H10D 84/0149; H10D 84/832; H10W 20/427

(57) ABSTRACT

A semiconductor structure including a nanosheet stack comprising a series of channel nanosheets, a gate structure, first inner spacers, second inner spacers, and a self-aligned backside cap, where the self-aligned backside cap is immediately below the gate structure and between the second inner spacers.

### BACKGROUND

The present invention generally relates to semiconductor structures, and more particularly to nanosheet transistor structures having self-aligned backside self-aligned caps enabling formation of direct backside contacts without requiring a placeholder fabrication scheme.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a nanosheet stack having a series of channel nanosheets, a gate structure, first inner spacers, second inner spacers, and a self-aligned backside cap, where the self-aligned backside cap is immediately below the gate structure and between the second inner spacers.

According to another embodiment of the present invention, a semiconductor structure is provided. The semiconductor structure may include a nanosheet stack having a series of channel nanosheets, a gate structure, first inner spacers, second inner spacers, and a self-aligned backside cap, where a height of the first inner spacers is less than a height of the second inner spacers, and where the self-aligned backside cap is immediately below the gate structure and between the second inner spacers.

According to another embodiment of the present invention, a semiconductor structure is provided. The semiconductor structure may include a nanosheet stack having a series of channel nanosheets, a gate structure, first inner spacers, second inner spacers, and a self-aligned backside cap, where the self-aligned backside cap is immediately below the gate structure and between the second inner spacers, and where bottommost surfaces of the second inner spacers is substantially flush with a bottommost surface of the self-aligned backside cap.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating nanosheet transistor structures according to an exemplary embodiment;

FIGS. 5, 6, and 7 are cross-sectional views of the semiconductor structure after forming and patterning sacrificial gates and forming gate spacers according to an exemplary embodiment;

FIGS. 8, 9, and 10 are cross-sectional views of the semiconductor structure after forming individual nanosheet stacks and source drain openings according to an exemplary embodiment;

FIGS. 11, 12, and 13 are cross-sectional views of the semiconductor structure after forming an inner spacer material according to an exemplary embodiment;

FIGS. 14, 15, and 16 are cross-sectional views of the semiconductor structure after forming inner spacers according to an exemplary embodiment;

FIGS. 17, 18, and 19 are cross-sectional views of the semiconductor structure after forming source drain regions and a dielectric layer according to an exemplary embodiment;

FIGS. 20, 21, and 22 are cross-sectional views of the semiconductor structure after selectively removing the sacrificial gates and the sacrificial nanosheets, forming gate structures, and forming self-aligned frontside gate caps according to an exemplary embodiment;

FIGS. 23, 24, and 25 are cross-sectional views of the semiconductor structure after forming middle-of-line, back-end-of-line, and attaching a carrier wafer according to an exemplary embodiment;

FIGS. 26, 27, and 28 are cross-sectional views of the semiconductor structure after flipping the assembly and recessing the substrate according to an exemplary embodiment;

FIGS. 29, 30, and 31 are cross-sectional views of the semiconductor structure after removing and recessing remaining portions of the substrate according to an exemplary embodiment;

FIGS. 32, 33, and 34 are cross-sectional views of the semiconductor structure after recessing the gate structures according to an exemplary embodiment;

FIGS. 35, 36, and 37 are cross-sectional views of the semiconductor structure after forming self-aligned backside caps according to an exemplary embodiment;

FIGS. 38, 39, and 40 are cross-sectional views of the semiconductor structure forming a backside dielectric layer according to an exemplary embodiment; and

FIGS. 41, 42, and 43 are cross-sectional views of the semiconductor structure after forming a backside contact structures and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional placeholder fabrication techniques run the risk of causing damage to the gate hard mask, resulting spacer loss and epi nodules. The placeholder-based backside contact also involves high aspect ratio patterning, which increases risk of gate bending or collapse. Therefore, it is desired to form backside contacts without need of creating deep placeholders under source drain regions.

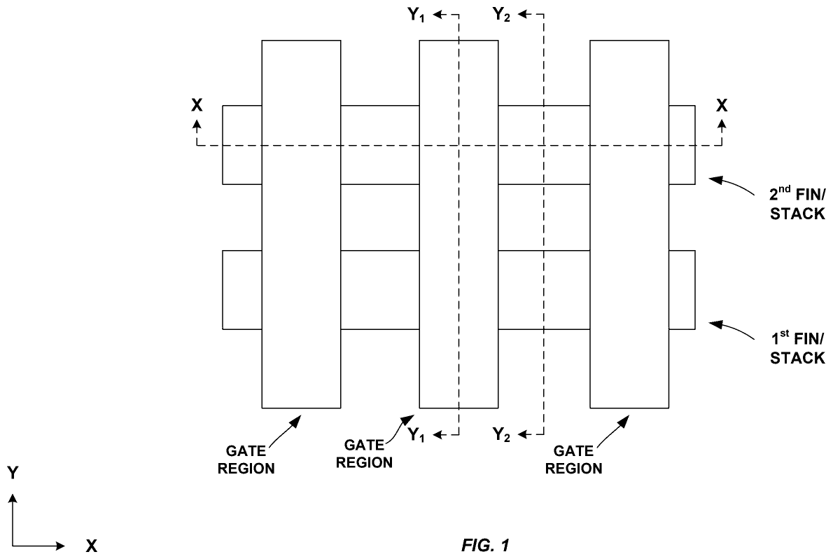

The present invention generally relates to semiconductor structures, and more particularly to nanosheet transistor structures having self-aligned backside caps enabling formation of direct backside contacts without requiring a placeholder fabrication scheme. More specifically, the nanosheet transistor structures and associated method disclosed herein enable a novel solution for forming direct backside contacts using the self-aligned backside caps to electrically isolate the direct backside contacts and the gate. Further, the self-aligned backside caps prevent shorting between the direct backside contacts and the gate. Exemplary embodiments of nanosheet transistor structures having self-aligned backside caps are described in detail below by referring to the accompanying drawings in FIGS. 1 to 43. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows a first fin/stack, a second fin/stack, and gate regions situated perpendicular to the fins/stacks. FIGS. 1-43 represent cross section views oriented as indicated in FIG. 1

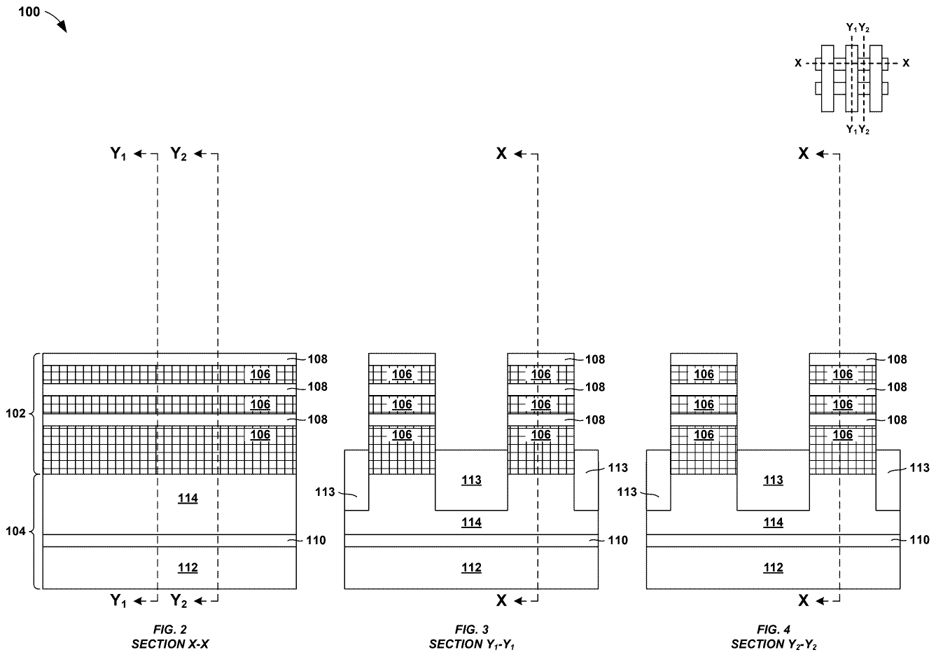

Referring now to FIGS. 2, 3, and 4, a structure 100 is shown during an intermediate step of a method of fabricating stacked transistor structures according to an embodiment of the invention. FIG. 2 depicts a cross-sectional view of the structure 100 taken along line X-X, FIG. 3 depicts a cross-sectional view of the structure 100 taken along line Y₁-Y₁, and FIG. 4 depicts a cross-sectional view of the structure 100 taken along line Y₂-Y₂.

The structure 100 illustrated in FIGS. 2-4 includes nanosheet layers 102 formed on a substrate 104. For purposes of orientation, the substrate 104 is herein referred to as being on a “backside” of the structure 100 and the nanosheet layers 102 are herein referred to as being on a “frontside” of the structure 100. Further, certain features may be described herein as having a relative position with respect to the frontside or backside of the structure 100.

The nanosheet layers 102 include an alternating series of silicon germanium (SiGe) sacrificial nanosheets 106 (hereinafter “sacrificial nanosheets 106”) and silicon (Si) channel nanosheets 108 (hereinafter “channel nanosheets 108”), as illustrated. Although only a limited number of the nanosheet layers 102 are shown, one or more additional nanosheet layers and/or nanosheets can optionally be epitaxially grown in an alternating fashion, and the properties of any additional nanosheets are the same as the corresponding nanosheets described herein.

In one or more embodiments, the nanosheet layers 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, the channel nanosheets 108 of the nanosheet layers 102 may be doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 104 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 104 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure.

Known processing techniques have been applied to the alternating layers to form the nanosheet layers 102 shown. For example, the known processing techniques can include the formation of hard masks (not shown) over the topmost layer of the nanosheet layers 102. The hard masks can be formed by first depositing the hard mask material (for example silicon nitride) onto the topmost layer of the nanosheet layers 102 using, for example, chemical vapor deposition (CVD), plasma enhanced CVD (PECVD) or any suitable technique for dielectric deposition that does not induce a physical or chemical change to the topmost layer of the nanosheet layers 102. According to an exemplary embodiment, the hard mask material is deposited onto the topmost channel nanosheet (108) at the top of the nanosheet layers 102 and then patterned into a plurality of the individual hard masks. Patterning the hard mask is commensurate with a desired footprint and location of the nanosheet layers 102 shown in FIGS. 2-4, which will subsequently be used to form the channel regions of semiconductor devices disclosed herein. According to an exemplary embodiment, RIE is used to transfer the hard mask pattern into the alternating layers to form the nanosheet layers 102, and into the substrate 104, as shown.

Next, shallow trench isolation regions 113 (hereinafter “STI regions 113”) are formed according to known techniques. The STI regions 113 are formed at the bottom of trenches in the substrate 104 formed during patterning of the nanosheet layers 102. Specifically, a dielectric material is deposited at the bottom of trenches in the substrate 104 to isolate adjacent devices from one another according to known techniques. The STI regions 113 may be formed from any appropriate dielectric material including, for example, silicon oxide (SiOₓ) or silicon nitride (SiₓN_{y}).

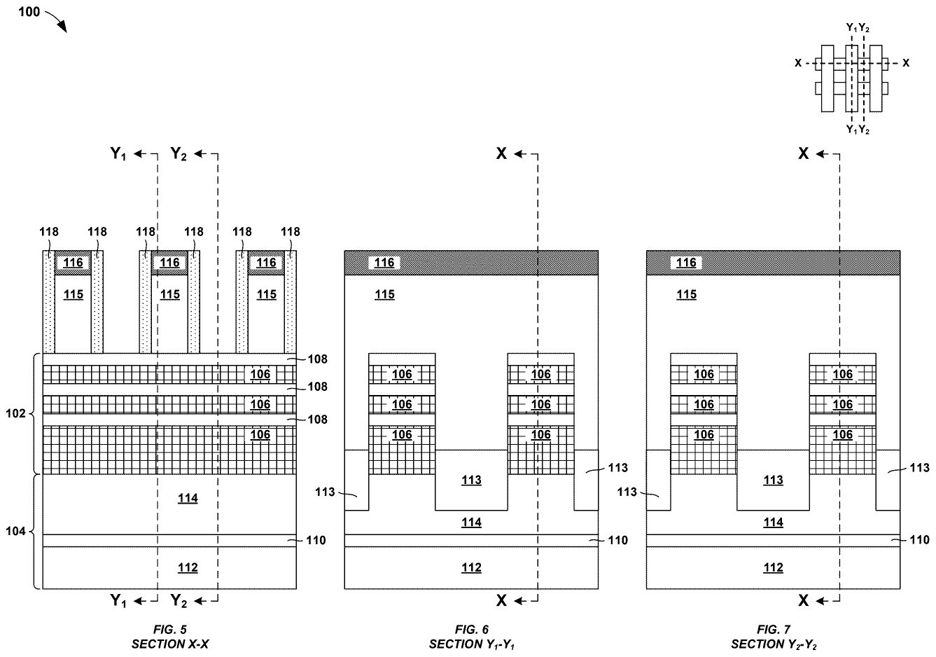

Referring now to FIGS. 5, 6, and 7, the structure 100 is shown after forming and patterning sacrificial gates 115 and forming gate spacers 118 according to an embodiment of the invention. FIG. 5 depicts a cross-sectional view of the structure 100 taken along line X-X, FIG. 6 depicts a cross-sectional view of the structure 100 taken along line Y₁-Y₁, and FIG. 7 depicts a cross-sectional view of the structure 100 taken along line Y₂-Y₂.

First, a sacrificial gate material is blanket deposited over and around the nanosheet layers 102 according to known techniques. Specifically, for example, a relatively thick layer of amorphous silicon is blanket deposited directly on the nanosheet layers 102. In this manner, the sacrificial gate material completely covers structure 100, and specifically the nanosheet layers 102.

Next, a gate hard mask material is formed over the structure 100. According to an exemplary embodiment, the gate hard mask material is deposited directly onto the sacrificial gate material and then patterned into a plurality of gate hard masks 116 or alternatively individual masks 116. In general, the gate hard masks 116 define gate regions of individual devices in the structure 100. Patterning the hard mask material is commensurate with a desired footprint and location of a device layout.

Next, the pattern created by the gate hard masks 116 is transferred into the sacrificial gate material to form the sacrificial gates 115. Specifically, portions of the sacrificial gate material are etched or removed selective to the gate hard masks 116, as illustrated. The portions of the sacrificial gate material can be removed using a silicon RIE process.

Next, the gate spacers 118 are formed directly on exposed sidewalls of the structure 100 according to known techniques. Specifically, for example, a relatively thin layer of dielectric material is conformally deposited. After deposition, in at least an embodiment, portions of the dielectric material are selectively removed or etched from horizontal surfaces according to known techniques. Doing so will generally expose top surfaces of the nanosheet layers 102 and the gate hard masks 116, as illustrated in FIG. 5.

In some embodiments, for example, the gate spacers 118 may be composed of SiN, SiBCN, SiOCN, SiOC, or any other combination of low-k materials. The term “low-k” as used throughout the present application denotes a dielectric material that has a dielectric constant of less than 4.0.

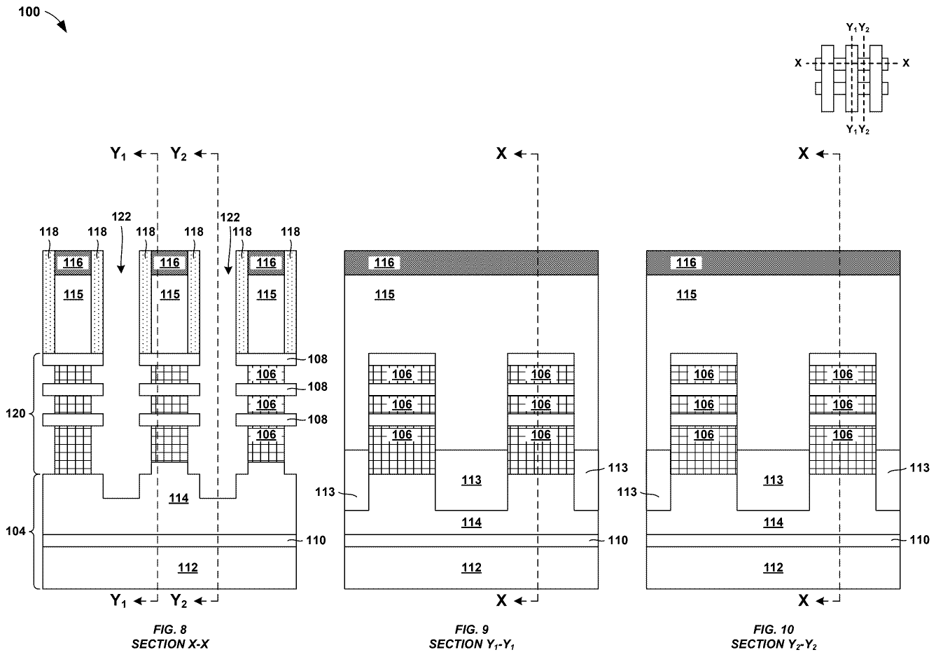

Referring now to FIGS. 8, 9, and 10, the structure 100 is shown after forming individual nanosheet stacks 120 and source drain openings 122 according to an embodiment of the invention. FIG. 8 depicts a cross-sectional view of the structure 100 taken along line X-X, FIG. 9 depicts a cross-sectional view of the structure 100 taken along line Y₁-Y₁, and FIG. 10 depicts a cross-sectional view of the structure 100 taken along line Y₂-Y₂.

First, portions of the nanosheet layers 102 are etched and removed from between the sacrificial gates 115 according to known techniques. Specifically, the pattern created by the gate hard masks 116 and the gate spacers 118 is transferred into the nanosheet layers 102 to create the individual nanosheet stacks 120, as illustrated. In doing so, portions of the sacrificial nanosheets 106 and the channel nanosheets 108 are removed selective to the gate spacers 118.

In an embodiment, portions of the nanosheet layers 102 are removed using an anisotropic etch such as, for example, reactive ion etching. Doing so may require a series of multiple etching steps using different etch chemistries as is well known in the art. Etching is designed to expose ends of individual nanosheet layers and define the source drain openings 122. According to the disclosed embodiments, etching continues into the substrate 104. Said differently, etching continues until the source drain openings 122 extend into a the top semiconductor layer 114, as illustrated. Although an exact depth into the top semiconductor layer 114 is not critical, a bottom of the source drain openings 122 shall be somewhere below a top surface of the top semiconductor layer 114 and above a bottom surface of the STI regions 113.

Finally, after patterning the nanosheet layers 102 and creating the individual nanosheet stacks 120, the sacrificial nanosheets 106 are laterally recessed to make room for inner spacers according to known techniques. In one or more embodiments, the sacrificial nanosheets 106 are laterally recessed using a hydrogen chloride (HCL) gas isotropic etch process, which etches silicon germanium without attacking silicon. In other embodiments, the sacrificial nanosheets 106 are laterally recessed using a ClF3 etch process. As illustrated, cavities are formed by spaces that were occupied by the removed portions of the sacrificial nanosheets 106.

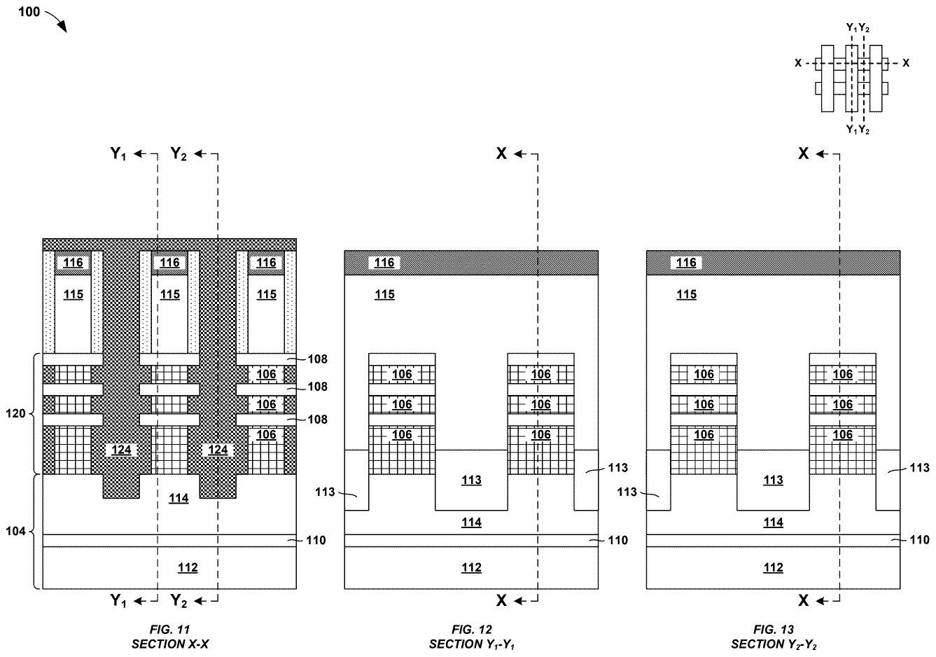

Referring now to FIGS. 11, 12, and 13, the structure 100 is shown after forming an inner spacer material 124 according to an embodiment of the invention. FIG. 11 depicts a cross-sectional view of the structure 100 taken along line X-X, FIG. 12 depicts a cross-sectional view of the structure 100 taken along line Y₁-Y₁, and FIG. 13 depicts a cross-sectional view of the structure 100 taken along line Y₂-Y₂.

The inner spacer material 124 is blanket deposited across the structure 100 according to known techniques. The inner spacer material 124 may be composed of a nitride containing material, for example silicon nitride (SiN).

In an embodiment, the inner spacer material 124 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering. According to the disclosed embodiment, the inner spacer material 124 shall be deposited to sufficiently fill or pinch-off the source drain openings 122, as illustrated.

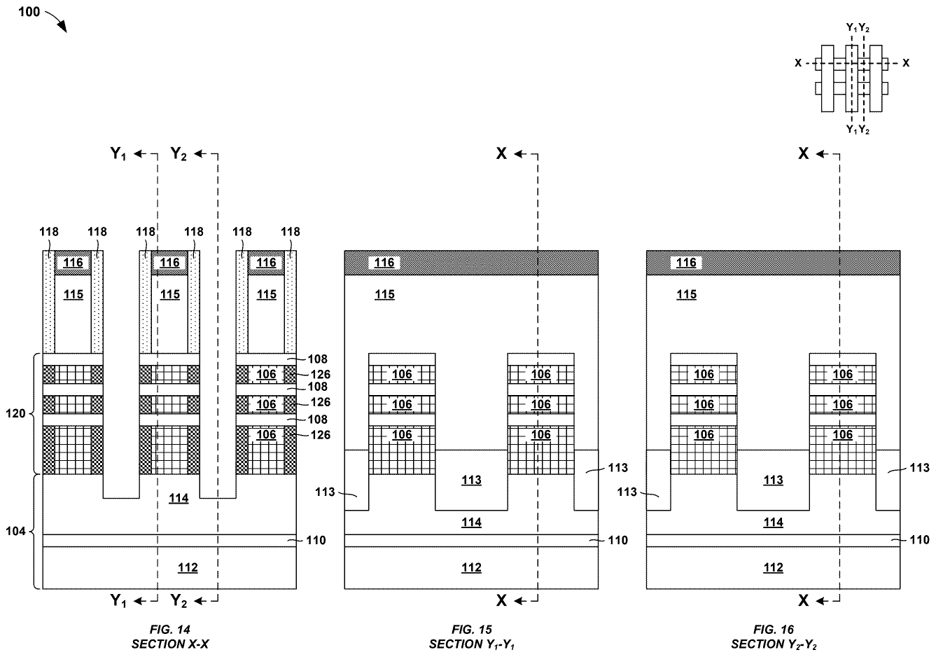

Referring now to FIGS. 14, 15, and 16, the structure 100 is shown after forming inner spacers 126 according to an embodiment of the invention. FIG. 14 depicts a cross-sectional view of the structure 100 taken along line X-X, FIG. 15 depicts a cross-sectional view of the structure 100 taken along line Y₁-Y₁, and FIG. 16 depicts a cross-sectional view of the structure 100 taken along line Y₂-Y₂.

In an embodiment, portions of the inner spacer material 124 are removed using an anisotropic etch such as, for example, reactive ion etching. Etching is designed to re-open the source drain openings 122 while leaving portions of the inner spacer material 124 to form the inner spacers 126. In doing so, ends of the channel nanosheets 108 become exposed within the source drain openings 122, as illustrated.

The inner spacers 126 are disposed between the channel nanosheets 108 in each of the individual nanosheet stacks 120, and laterally separate subsequently formed gate structures from subsequently formed source drain regions, as illustrated in subsequent figures. Additionally, the inner spacers 126 are positioned such that subsequent etching processes used to remove the sacrificial nanosheets 106 during device fabrication do not also attack the subsequently formed source drain regions.

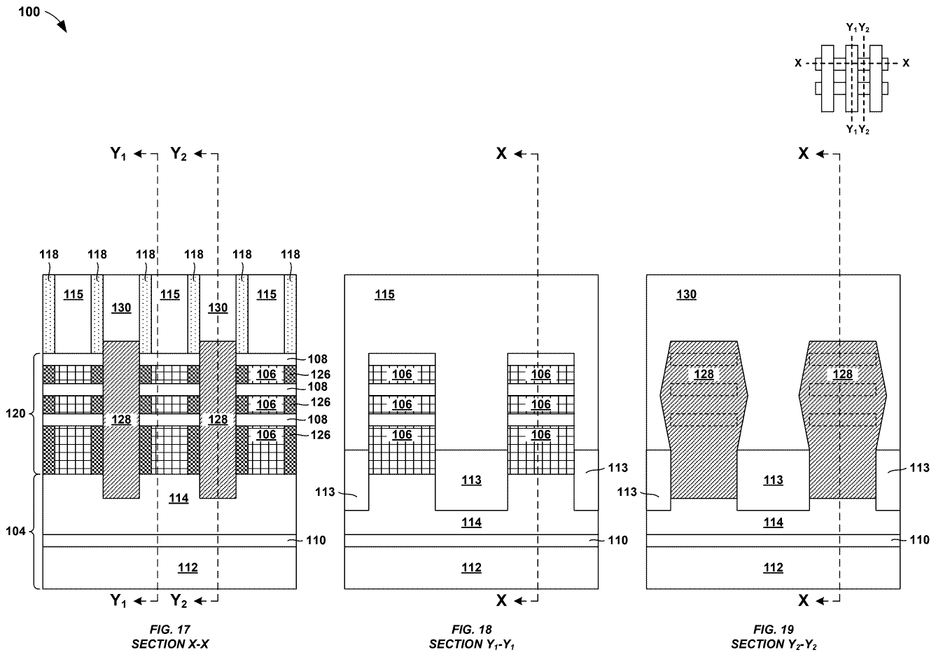

Referring now to FIGS. 17, 18, and 19, the structure 100 is shown after forming source drain regions 128 and a dielectric layer 130 according to an embodiment of the invention. FIG. 17 depicts a cross-sectional view of the structure 100 taken along line X-X, FIG. 18 depicts a cross-sectional view of the structure 100 taken along line Y₁-Y₁, and FIG. 19 depicts a cross-sectional view of the structure 100 taken along line Y₂-Y₂.

Next, the source drain regions 128 are formed using an epitaxial layer growth process on the exposed ends of the channel nanosheets 108 according to known techniques. Typically, in-situ doping is used to dope the source drain regions 128, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

According to embodiments of the present invention, at least some of the source drain regions 128 are of a first-type, for example, P-type, and at least some of the source drain regions 128 are of a second-type, for example, N-type.

Next, the dielectric layer 130 is blanket deposited an interlayer dielectric material over the structure 100 according to known techniques. Specifically, the dielectric layer 130 is formed on the source drain regions 128, as illustrated in FIG. 19, and substantially fills the remaining space between the gate spacers 118, as illustrated in FIG. 17.

The dielectric layer 130 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 130. Using a self-planarizing dielectric material as the dielectric layer 130 can avoid the need to perform a subsequent planarizing step.

After the dielectric layer 130 is formed, the backside of the structure 100 is polished according to known techniques, such as, for example, chemical mechanical polishing techniques. Specifically, the dielectric layer 130, the gate spacers 118, and the gate hard masks 116 are polished until the gate hard masks 116 are removed and topmost surfaces of the sacrificial gates 115 are exposed, as illustrated.

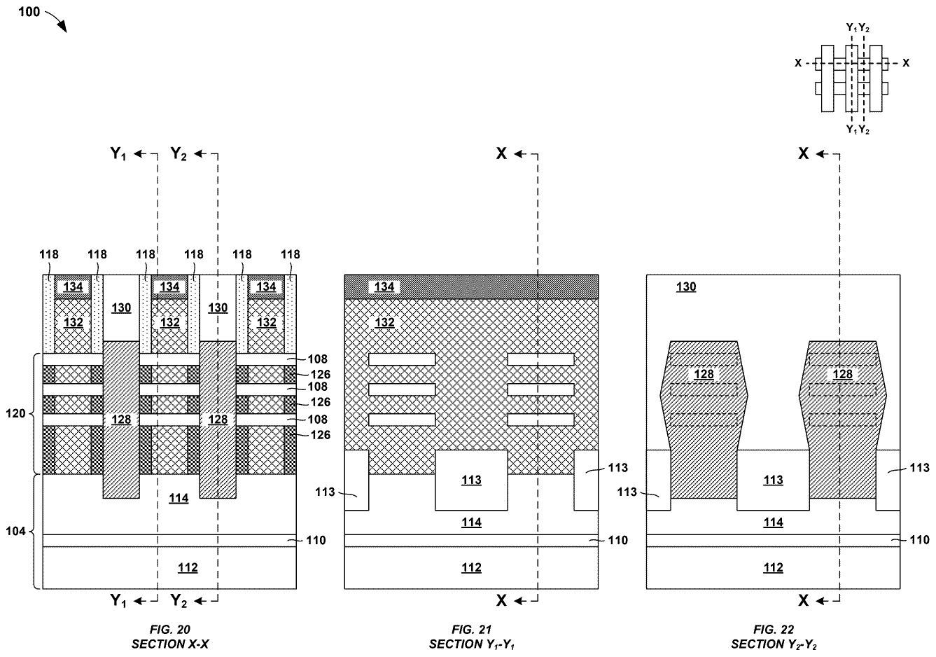

Referring now to FIGS. 20, 21, and 22, the structure 100 is shown after selectively removing the sacrificial gates 115 and the sacrificial nanosheets 106, forming gate structures 132, and forming self-aligned frontside gate caps 134 according to an embodiment of the invention. FIG. 20 depicts a cross-sectional view of the structure 100 taken along line X-X, FIG. 21 depicts a cross-sectional view of the structure 100 taken along line Y₁-Y₁, and FIG. 22 depicts a cross-sectional view of the structure 100 taken along line Y₂-Y₂.

First, the sacrificial gates 115 and the sacrificial nanosheets 106 are selectively removed according to known techniques. Specifically, the sacrificial gates 115 are etched and removed selective to the gate spacers 118 and the individual nanosheet stacks 120 according to known techniques. Next, the sacrificial nanosheets 106 are etched and removed selective to the channel nanosheets 108 and the inner spacers 126 according to known techniques. Doing so is made possible by the different concentrations of germanium. In this case, the layers with germanium are removed selective to layers without germanium.

The gate structures 132, include a gate dielectric and a work function metal, are formed according to known techniques. First, the gate dielectric (not shown) is conformally deposited directly on exposed surfaces of the structure 100 within the gate cavities or openings and spaces left by removing the sacrificial gates 115 and the sacrificial nanosheets 106 according to known techniques. For example, the gate dielectric is conformally deposited on exposed surfaces of the channel nanosheets 108 and the inner spacers 126.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, the work function metal (not shown) is conformally deposited on the gate dielectric formed within the gate cavities according to known techniques. In at least one embodiment, the work function metal is made of the same conductive material across the entire structure. In at least another embodiment, the work function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium alumunm (TiAl), titanium aluminum cabron (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, a gate metal or a contact metal, is deposited directly on the work function metal, and fills the gate cavities. The gate metal may include any suitable conductive material, such as, for example, copper, ruthenium, aluminum, tungsten, cobalt, or alloys thereof. After deposition, excess gate metal can be polished using known techniques.

Next, the self-aligned frontside gate caps 134 are formed according to known techniques. First, the gate structures 132 are recessed according to known techniques. Specifically, for example, one or more suitable etching techniques such as dry etch, wet etch, or combination of both may be used to recess the gate structures 132. In all cases, the chosen etching technique shall be selective to underlying structures, such as for example, the gate spacers 118 and the dielectric layer 130.

Next, the self-aligned frontside gate caps 134 of the present embodiment are formed directly on the recessed gate structures 132, and more specifically fill the voids created by recessing the gate structures 132 as illustrated and according to known techniques. Specifically, a first blanket dielectric layer is deposited across the structure 100 followed by a chemical mechanical polishing technique to remove excess unwanted dielectric material from upper surfaces of the structure 100. As a result, topmost surfaces of the self-aligned frontside gate caps 134 will be flush, or substantially flush, with topmost surfaces of the gate spacers 118 and the dielectric layer 130.

The gate spacers 118 and the self-aligned frontside gate caps 134 are provided to separate and electrically insulate the gate structures 132 from subsequently formed structures, such as, for example, contact structures. The gate spacers 118 are critical for electrically insulating the gate structures 132 from adjacent source drain regions 128 or subsequently formed contact structures, as described below. The self-aligned frontside gate caps 134 may further protect the gate structures 132 during subsequent processing. In at least one embodiment, the gate spacers 118 and the self-aligned frontside gate caps 134 are both composed of SiN, SiBCN, SiOCN, SiOC, or other known equivalents.

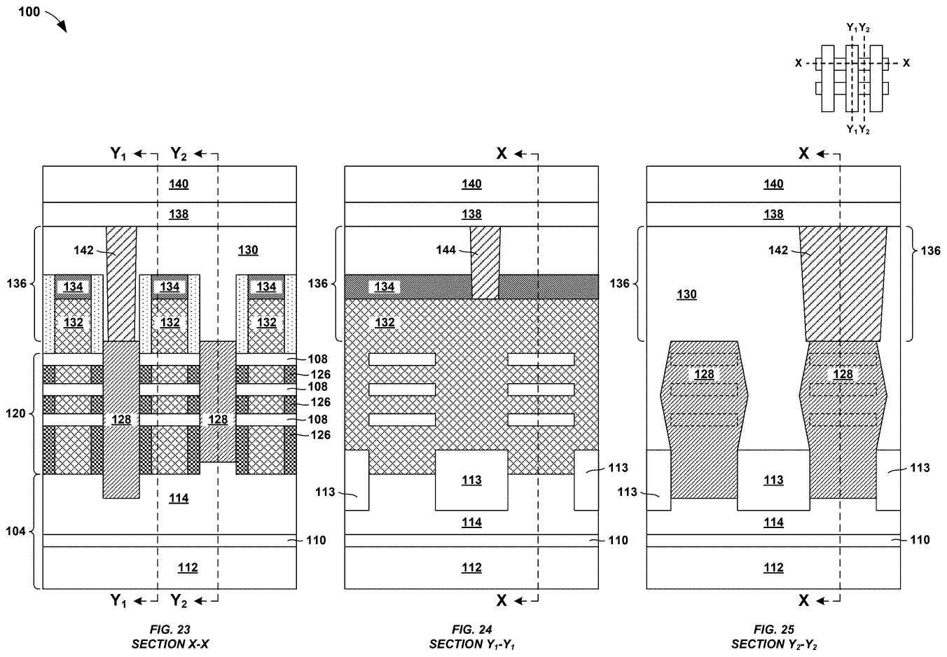

Referring now to FIGS. 23, 24, and 25, the structure 100 is shown after forming middle-of-line 136, back-end-of-line 138, and attaching a carrier wafer 140 according to an embodiment of the invention. FIG. 23 depicts a cross-sectional view of the structure 100 taken along line X-X, FIG. 24 depicts a cross-sectional view of the structure 100 taken along line Y₁-Y₁, and FIG. 25 depicts a cross-sectional view of the structure 100 taken along line Y₂-Y₂.

The middle-of-line 136 includes source drain contacts 142 and gate contacts 144 which may be generally referred to as middle-of-line contacts. The source drain contacts 142 and the gate contacts 144 are formed according to known techniques. First, additional interlayer dielectric material is deposited according to known techniques. The dielectric layer 130 illustrated in the figures includes the additional interlayer dielectric material. Next, portions of the dielectric layer 130 are removed to expose the source drain regions 128. The openings are then filled with a conductive material to form the middle-of-line contacts according to known techniques. The middle-of-line contacts include any suitable conductive material, such as, for example, copper, ruthenium, aluminum, tungsten, cobalt, or alloys thereof. In some embodiments, a metal silicide is formed at the bottom of the contact trenches prior to filling them with the conductive material.

The back-end-of-line 138 may include vias and metal lines which may be generally referred to as back-end-of-line interconnects. The vias and the metal lines are formed according to known techniques.

Finally, the carrier wafer 140 is secured to a top of the structure 100 according to an embodiment of the invention. The carrier wafer 140 is attached, or removably secured, to the back-end-of-line 138. In general, and not depicted, the carrier wafer 140 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 140 according to known techniques.

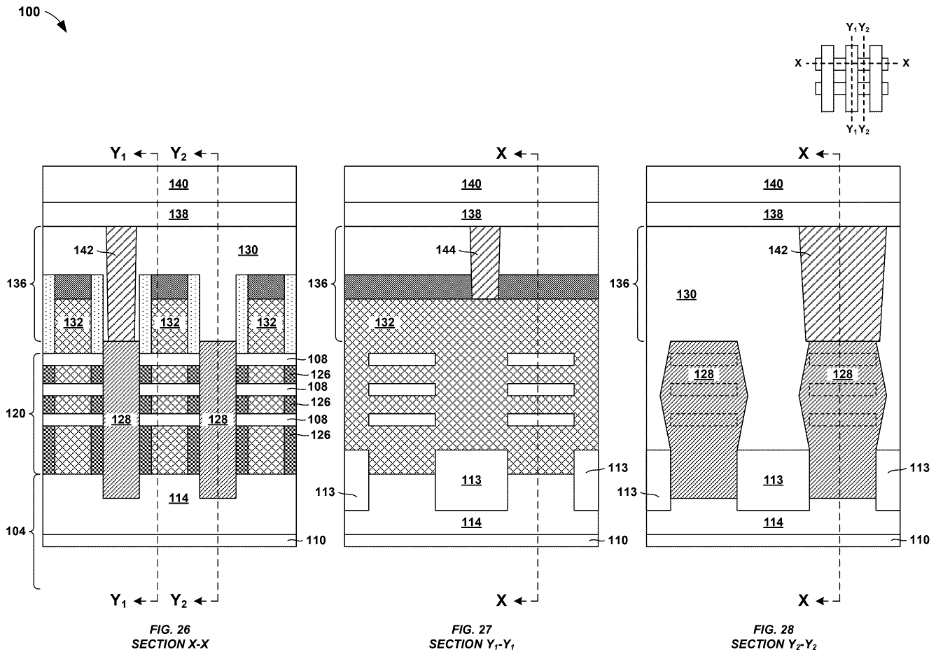

Referring now to FIGS. 26, 27, and 28, the structure 100 is shown after flipping the assembly and recessing the substrate 104 according to an embodiment of the invention. FIG. 26 depicts a cross-sectional view of the structure 100 taken along line X-X, FIG. 27 depicts a cross-sectional view of the structure 100 taken along line Y₁-Y₁, and FIG. 28 depicts a cross-sectional view of the structure 100 taken along line Y₂-Y₂.

First, the structure 100 is flipped 180 degrees to prepare for backside processing. In general, backside processing includes fabrication or processing of the structure 100 opposite the active device and wiring layers. Next, the substrate 104 is recessed according to known techniques. Specifically, the base substrate 112 is recessed or completely removed to expose the etch stop layer 110, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

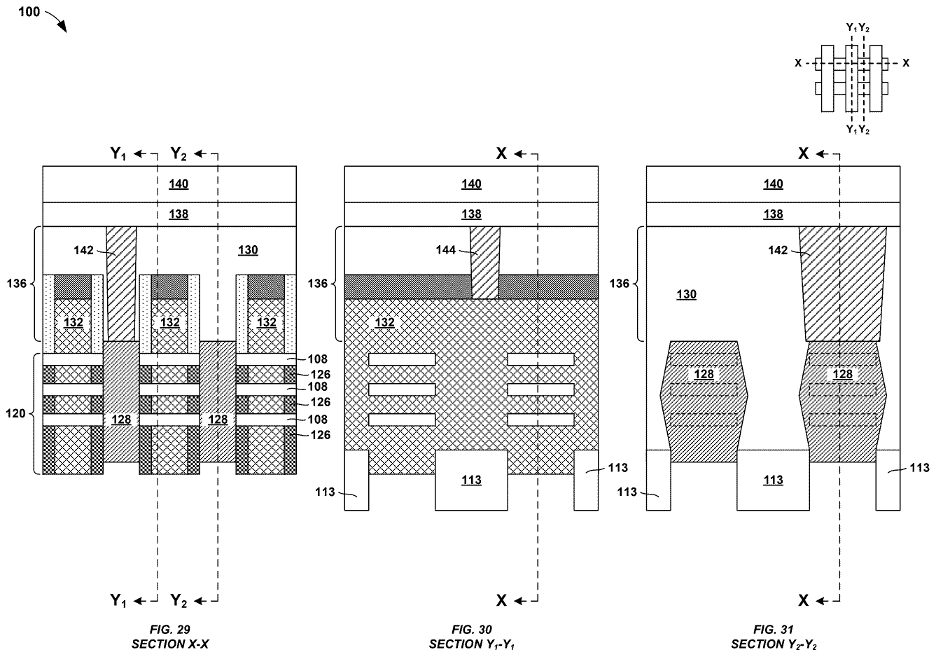

Referring now to FIGS. 29, 30, and 31, the structure 100 is shown after removing and recessing remaining portions of the substrate 104 according to an embodiment of the invention. FIG. 29 depicts a cross-sectional view of the structure 100 taken along line X-X, FIG. 30 depicts a cross-sectional view of the structure 100 taken along line Y₁-Y₁, and FIG. 31 depicts a cross-sectional view of the structure 100 taken along line Y₂-Y₂.

First, the etch stop layer 110 is selectively removed and the top semiconductor layer 114 is recessed according to known techniques. Specifically, the etch stop layer 110 is removed selective to the top semiconductor layer 114 and the top semiconductor layer 114 is removed selective to the inner spacers 126, the gate structures 132, and the STI regions 113, as illustrated. According to an embodiment, the source drain regions 128 may experience some erosion or etch back during recessing the top semiconductor layer 114. According to other embodiments, recessing the top semiconductor layer 114 continues until the source drain regions 128 experience some erosion or etch back. Stated differently, over etching the top semiconductor layer 114 may recess the source drain regions 128, as illustrated.

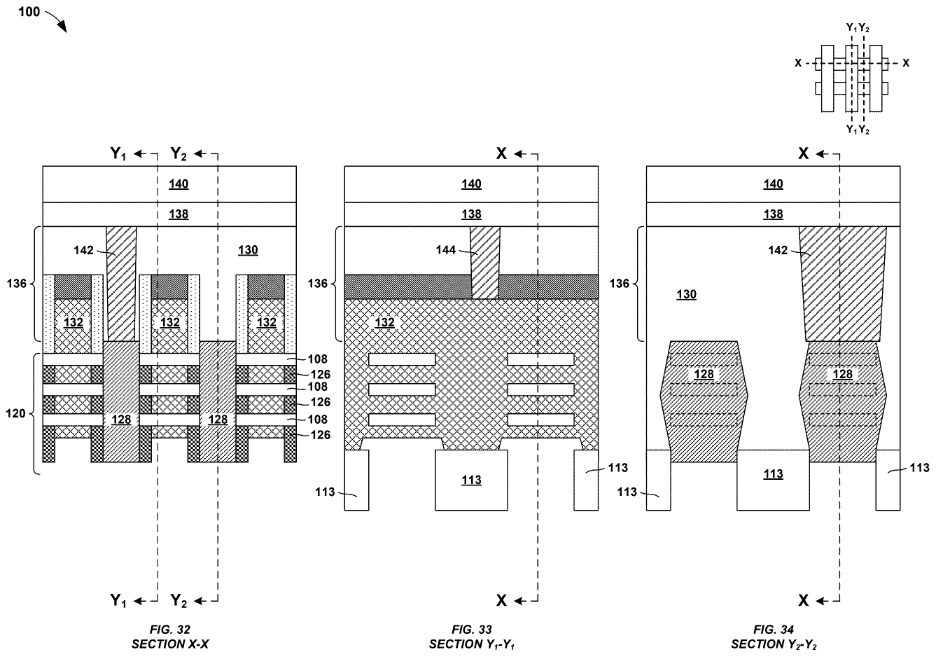

Referring now to FIGS. 32, 33, and 34, the structure 100 is shown after recessing the gate structures 132 according to an embodiment of the invention. FIG. 32 depicts a cross-sectional view of the structure 100 taken along line X-X, FIG. 33 depicts a cross-sectional view of the structure 100 taken along line Y₁-Y₁, and FIG. 34 depicts a cross-sectional view of the structure 100 taken along line Y₂-Y₂.

The gate structures 132 are recessed according to known techniques. Specifically, for example, one or more suitable etching techniques such as dry etch, wet etch, or combination of both may be used to recess the gate structures 132 from the backside of the structure 100, as illustrated in FIG. 32. In all cases, the chosen etching technique shall be selective to surrounding structures, such as for example, the inner spacers 126 and the source drain regions 128.

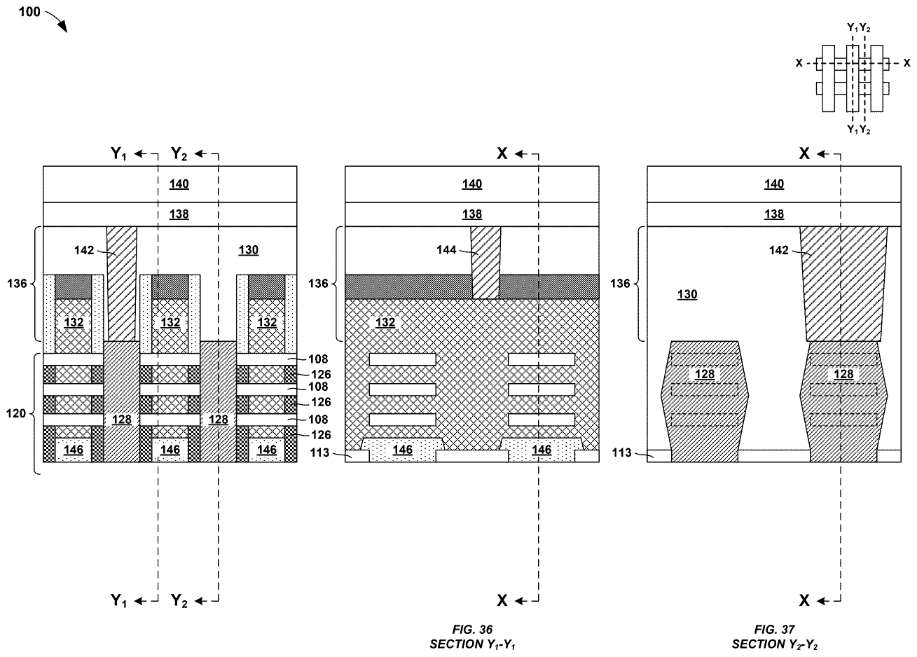

Referring now to FIGS. 35, 36, and 37, the structure 100 is shown after forming self-aligned backside caps 146 according to an embodiment of the invention. FIG. 35 depicts a cross-sectional view of the structure 100 taken along line X-X, FIG. 36 depicts a cross-sectional view of the structure 100 taken along line Y₁-Y₁, and FIG. 37 depicts a cross-sectional view of the structure 100 taken along line Y₂-Y₂.

Next, the self-aligned backside caps 146 of the present embodiment are formed directly on the recessed gate structures 132, and more specifically fill the voids created by recessing the gate structures 132 as illustrated and according to known techniques. Specifically, a second blanket dielectric layer is deposited across the backside of the structure 100 followed by a chemical mechanical polishing technique to remove excess unwanted dielectric material from bottom surfaces of the structure 100. As a result, bottommost surfaces of the self-aligned backside caps 146 will be flush, or substantially flush, with bottommost surfaces of the inner spacers 126 and the source drain regions 128, as illustrated in FIG. 35. Additionally, polishing will recess the STI regions 113. In doing so, bottommost surfaces of the STI regions 113 will be flush, or substantially flush, with bottommost surfaces of the self-aligned backside caps 146, as illustrated in FIG. 36.

The self-aligned backside caps 146 are provided to separate and electrically insulate the gate structures 132 from subsequently formed backside structures, such as, for example, backside contact structures. The self-aligned backside caps 146 may further protect the gate structures 132 during subsequent backside processing. In at least one embodiment, the self-aligned backside caps 146 are composed of SiN, SiBCN, SiOCN, SiOC, or other known equivalents.

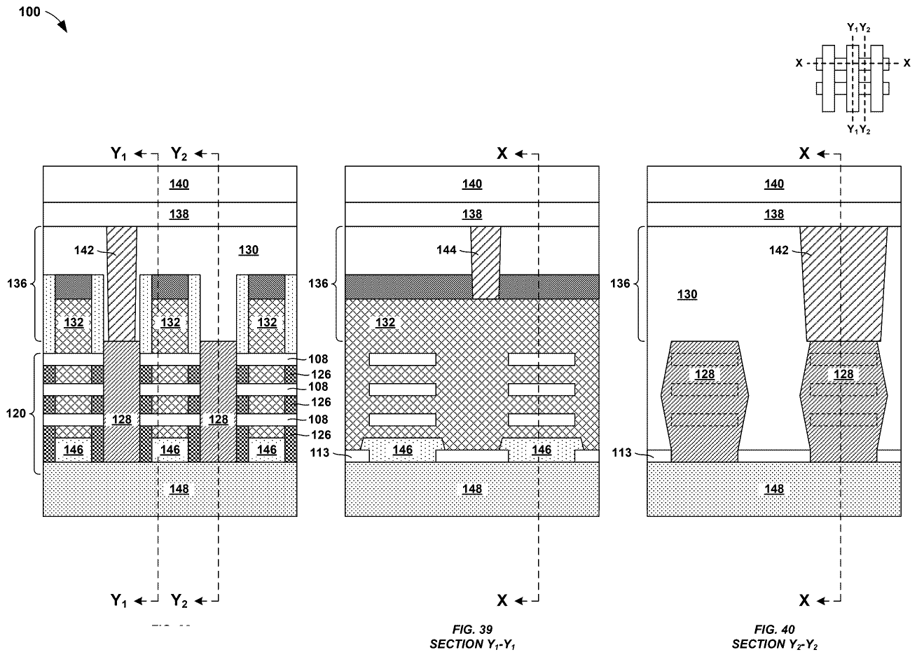

Referring now to FIGS. 38, 39, and 40, the structure 100 is shown after forming a backside dielectric layer 148 according to an embodiment of the invention. FIG. 38 depicts a cross-sectional view of the structure 100 taken along line X-X, FIG. 39 depicts a cross-sectional view of the structure 100 taken along line Y₁-Y₁, and FIG. 40 depicts a cross-sectional view of the structure 100 taken along line Y₂-Y₂.

The backside dielectric layer 148 is formed by blanket depositing an interlayer dielectric material over the backside of the structure 100 according to known techniques. Specifically, the backside dielectric layer 148 is formed on and covers exposed bottoms surfaces of the gate spacers 118, the gate structures 132, and the source drain regions 128, as illustrated.

The backside dielectric layer 148 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the backside dielectric layer 148. Using a self-planarizing dielectric material as the backside dielectric layer 148 can avoid the need to perform a subsequent planarizing step.

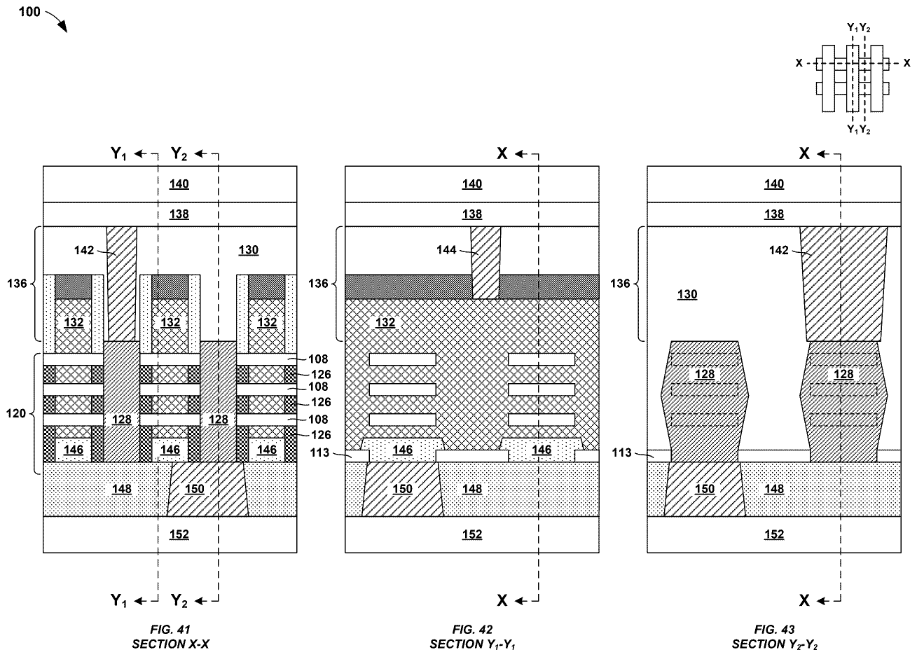

Referring now to FIGS. 41, 42, and 43, the structure 100 is shown after forming a backside contact structures 150 and backside wiring layers 152 according to an embodiment of the invention. FIG. 38 depicts a cross-sectional view of the structure 100 taken along line X-X, FIG. 39 depicts a cross-sectional view of the structure 100 taken along line Y₁-Y₁, and FIG. 40 depicts a cross-sectional view of the structure 100 taken along line Y₂-Y₂.

First, a mask (not shown) is deposited and subsequently patterned to expose certain portions of the structure 100 according to known techniques. According to at least one embodiment, the mask can be an organic planarization layer (OPL) or a layer of material that is capable of being planarized or etched by known techniques. After depositing the mask, a dry etching technique is applied to pattern or recess the mask according to known techniques. The mask is patterned consistent with a size and a location of subsequently formed backside contact structures.

Exposed portions of the backside dielectric layer 148 are then selectively removed to form backside trenches (not shown) according to known techniques. Specifically, exposed portions of the backside dielectric layer 148 are removed using known etching techniques suitable to remove silicon-based dielectric materials selective to the mask. In an embodiment, the exposed portions of the backside dielectric layer 148 are removed using an anisotropic etch such as, for example, reactive ion etching (RIE).

Next, the backside contact trenches are filled with a conductive material to form the backside contact structures 150 according to known techniques. The backside contact structures 150 may include any suitable conductive material, such as, for example, copper, ruthenium, aluminum, tungsten, cobalt, or alloys thereof. Additionally, the backside contact structures 150 may alternatively be referred to as direct backside contacts.

After deposition, excess conductive material can be polished using known techniques until bottommost surfaces of the backside contact structures 150 are flush, or substantially flush, with bottommost surfaces of the backside dielectric layer 148, as illustrated. After polishing, bottommost surfaces of the backside contact structures 150 are substantially flat.

Finally, after forming the backside contact structures 150, the backside wiring layers 152 are subsequently formed according to known techniques. The backside wiring layers 152 typically include at least backside power rails and a backside power delivery network.

According to the embodiment illustrated in FIGS. 41-43, the transistor structures represented by the structure 100 have some distinctive notable features. For instance, the nanosheet stacks 120 include self-aligned backside caps 146 enabling formation of direct backside contacts without requiring a placeholder fabrication scheme. More specifically, the self-aligned backside caps 146 electrically isolate the backside contact structures 150 from the gate structures 132 without the need for a placeholder scheme or other isolation technique. Further, the self-aligned backside caps 146 prevent shorting between the direct backside contacts and the gate.

It is noted, the backside contact structures 150 are formed in direct electrical contact with the self-aligned backside caps 146, as illustrated. Additionally, the inner spacers 126 of each nanosheet stack 120 have different heights. Specifically, the bottommost inner spacers 126 are taller than the rest of the inner spacers 126. Doing so provides the additional process margin for recessing the gate structure 132 from the backside and forming the self-aligned backside caps 146, as described in detail above.

With continued reference to FIGS. 41-43, and according to an embodiment, the structure 100 includes a nanosheet stack having a series of channel nanosheets, a gate structure, first inner spacers, second inner spacers, and a self-aligned backside cap, where the self-aligned backside cap is immediately below the gate structure and between the second inner spacers.

With continued reference to FIGS. 41-43, and according to an embodiment, the structure further includes a source drain region adjacent to the nanosheet stack, wherein a bottommost surface of the source drain region is substantially flush with a bottommost surface of the self-aligned backside cap.

With continued reference to FIGS. 41-43, and according to an embodiment, the structure further includes a backside contact structure in direct contact with the bottommost surface of the source drain region and the bottommost surface of the self-aligned backside cap.

With continued reference to FIGS. 41-43, and according to an embodiment, a lateral width of the self-aligned backside cap is larger than a lateral width of each channel nanosheet in the series of channel nanosheets measured in a direction parallel to the gate structure.

With continued reference to FIGS. 41-43, and according to an embodiment, a lateral length of the self-aligned backside cap is substantially equal to a lateral length of the gate structure measured in a direction perpendicular to the gate structure.

With continued reference to FIGS. 41-43, and according to an embodiment, the self-aligned backside cap is laterally offset from a source drain region in a direction perpendicular to the gate structure.

With continued reference to FIGS. 41-43, and according to an embodiment, the structure further includes a frontside gate cap above and in direct contact with a topmost surface of the gate structure, wherein the gate structure and the frontside gate cap both extend continuously across the nanosheet stack and at least one adjacent nanosheet stack.

With continued reference to FIGS. 41-43, and according to an embodiment, the structure 100 includes a nanosheet stack having a series of channel nanosheets, a gate structure, first inner spacers, second inner spacers, and a self-aligned backside cap, where a height of the first inner spacers is less than a height of the second inner spacers, and where the self-aligned backside cap is immediately below the gate structure and between the second inner spacers.

With continued reference to FIGS. 41-43, and according to an embodiment, the structure 100 includes a nanosheet stack having a series of channel nanosheets, a gate structure, first inner spacers, second inner spacers, and a self-aligned backside cap, where the self-aligned backside cap is immediately below the gate structure and between the second inner spacers, and where bottommost surfaces of the second inner spacers is substantially flush with a bottommost surface of the self-aligned backside cap.

Various examples may possibly be described by one or more of the following features in the following numbered clauses:

Clause 1: A semiconductor structure comprising: a nanosheet stack comprising a series of channel nanosheets, a gate structure, first inner spacers, second inner spacers, and a self-aligned backside cap, wherein the self-aligned backside cap is immediately below the gate structure and between the second inner spacers.

Clause 2: The semiconductor structure according to clause 1, further comprising: a source drain region adjacent to the nanosheet stack, wherein a bottommost surface of the source drain region is substantially flush with a bottommost surface of the self-aligned backside cap.

Clause 3: The semiconductor structure according to clauses 1 and 2, further comprising: a backside contact structure in direct contact with the bottommost surface of the source drain region and the bottommost surface of the self-aligned backside cap.

Clause 4: The semiconductor structure according to clauses 1, 2, and 3, wherein a lateral width of the self-aligned backside cap is larger than a lateral width of each channel nanosheet in the series of channel nanosheets measured in a direction parallel to the gate structure.

Clause 5: The semiconductor structure according to clauses 1, 2, 3, and 4, wherein a lateral length of the self-aligned backside cap is substantially equal to a lateral length of the gate structure measured in a direction perpendicular to the gate structure.

Clause 6: The semiconductor structure according to clauses 1, 2, 3, 4, and 5, wherein the self-aligned backside cap is laterally offset from a source drain region in a direction perpendicular to the gate structure.

Clause 7: The semiconductor structure according to clauses 1, 2, 3, 4, 5, and 6, further comprising: a frontside gate cap above and in direct contact with a topmost surface of the gate structure, wherein the gate structure and the frontside gate cap both extend continuously across the nanosheet stack and at least one adjacent nanosheet stack.

Clause 8: A semiconductor structure comprising: a nanosheet stack comprising a series of channel nanosheets, a gate structure, first inner spacers, second inner spacers, and a self-aligned backside cap, wherein a height of the first inner spacers is less than a height of the second inner spacers, and wherein the self-aligned backside cap is immediately below the gate structure and between the second inner spacers.

Clause 9: The semiconductor structure according to clause 8, further comprising: a source drain region adjacent to the nanosheet stack, wherein a bottommost surface of the source drain region is substantially flush with a bottommost surface of the self-aligned backside cap.

Clause 10: The semiconductor structure according to clauses 8 and 9, further comprising: a backside contact structure in direct contact with the bottommost surface of the source drain region and the bottommost surface of the self-aligned backside cap.

Clause 11: The semiconductor structure according to clauses 8, 9, and 10, wherein a lateral width of the self-aligned backside cap is larger than a lateral width of each channel nanosheet in the series of channel nanosheets measured in a direction parallel to the gate structure.

Clause 12: The semiconductor structure according to clauses 8, 9, 10, and 11, wherein a lateral length of the self-aligned backside cap is substantially equal to a lateral length of the gate structure measured in a direction perpendicular to the gate structure.

Clause 13: The semiconductor structure according to clauses 8, 9, 10, 11, and 12, wherein the self-aligned backside cap is laterally offset from a source drain region in a direction perpendicular to the gate structure.

Clause 14: The semiconductor structure according to clauses 8, 9, 10, 11, 12, and 13, further comprising: a frontside gate cap above and in direct contact with a topmost surface of the gate structure, wherein the gate structure and the frontside gate cap both extend continuously across the nanosheet stack and at least one adjacent nanosheet stack.

Clause 15: A semiconductor structure comprising: a nanosheet stack comprising a series of channel nanosheets, a gate structure, first inner spacers, second inner spacers, and a self-aligned backside cap, wherein the self-aligned backside cap is immediately below the gate structure and between the second inner spacers, and wherein bottommost surfaces of the second inner spacers is substantially flush with a bottommost surface of the self-aligned backside cap.

Clause 16: The semiconductor structure according to clause 15, further comprising: a source drain region adjacent to the nanosheet stack, wherein a bottommost surface of the source drain region is substantially flush with a bottommost surface of the self-aligned backside cap.

Clause 17: The semiconductor structure according to clauses 15 and 16, further comprising: a backside contact structure in direct contact with the bottommost surface of the source drain region and the bottommost surface of the self-aligned backside cap.

Clause 18: The semiconductor structure according to clauses 15, 16, and 17, wherein a lateral width of the self-aligned backside cap is larger than a lateral width of each channel nanosheet in the series of channel nanosheets measured in a direction parallel to the gate structure.

Clause 19: The semiconductor structure according to clauses 15, 16, 17, and 18, wherein a lateral length of the self-aligned backside cap is substantially equal to a lateral length of the gate structure measured in a direction perpendicular to the gate structure.

Clause 20: The semiconductor structure according to clauses 15, 16, 17, 18 and 19, wherein the self-aligned backside cap is laterally offset from a source drain region in a direction perpendicular to the gate structure.

What is claimed is:

1. A semiconductor structure comprising:
a nanosheet stack comprising a series of channel nanosheets, a gate structure, first inner spacers, second inner spacers, and a self-aligned backside cap, wherein the self-aligned backside cap is immediately below the gate structure and between the second inner spacers.

2. The semiconductor structure according to claim 1, further comprising:
a source drain region adjacent to the nanosheet stack, wherein a bottommost surface of the source drain region is substantially flush with a bottommost surface of the self-aligned backside cap.

3. The semiconductor structure according to claim 2, further comprising:
a backside contact structure in direct contact with the bottommost surface of the source drain region and the bottommost surface of the self-aligned backside cap.

4. The semiconductor structure according to claim 1, wherein a lateral width of the self-aligned backside cap is larger than a lateral width of each channel nanosheet in the series of channel nanosheets measured in a direction parallel to the gate structure.

5. The semiconductor structure according to claim 1, wherein a lateral length of the self-aligned backside cap is substantially equal to a lateral length of the gate structure measured in a direction perpendicular to the gate structure.

6. The semiconductor structure according to claim 1, wherein the self-aligned backside cap is laterally offset from a source drain region in a direction perpendicular to the gate structure.

7. The semiconductor structure according to claim 1, further comprising:
a frontside gate cap above and in direct contact with a topmost surface of the gate structure, wherein the gate structure and the frontside gate cap both extend continuously across the nanosheet stack and at least one adjacent nanosheet stack.

8. A semiconductor structure comprising:
a nanosheet stack comprising a series of channel nanosheets, a gate structure, first inner spacers, second inner spacers, and a self-aligned backside cap,
wherein a height of the first inner spacers is less than a height of the second inner spacers, and
wherein the self-aligned backside cap is immediately below the gate structure and between the second inner spacers.

9. The semiconductor structure according to claim 8, further comprising:
a source drain region adjacent to the nanosheet stack, wherein a bottommost surface of the source drain region is substantially flush with a bottommost surface of the self-aligned backside cap.

10. The semiconductor structure according to claim 9, further comprising:
a backside contact structure in direct contact with the bottommost surface of the source drain region and the bottommost surface of the self-aligned backside cap.

11. The semiconductor structure according to claim 8, wherein a lateral width of the self-aligned backside cap is larger than a lateral width of each channel nanosheet in the series of channel nanosheets measured in a direction parallel to the gate structure.

12. The semiconductor structure according to claim 8, wherein a lateral length of the self-aligned backside cap is substantially equal to a lateral length of the gate structure measured in a direction perpendicular to the gate structure.

13. The semiconductor structure according to claim 8, wherein the self-aligned backside cap is laterally offset from a source drain region in a direction perpendicular to the gate structure.

14. The semiconductor structure according to claim 8, further comprising:
a frontside gate cap above and in direct contact with a topmost surface of the gate structure, wherein the gate structure and the frontside gate cap both extend continuously across the nanosheet stack and at least one adjacent nanosheet stack.

15. A semiconductor structure comprising:
a nanosheet stack comprising a series of channel nanosheets, a gate structure, first inner spacers, second inner spacers, and a self-aligned backside cap,
wherein the self-aligned backside cap is immediately below the gate structure and between the second inner spacers, and
wherein bottommost surfaces of the second inner spacers is substantially flush with a bottommost surface of the self-aligned backside cap.

16. The semiconductor structure according to claim 15, further comprising:
a source drain region adjacent to the nanosheet stack, wherein a bottommost surface of the source drain region is substantially flush with a bottommost surface of the self-aligned backside cap.

17. The semiconductor structure according to claim 16, further comprising:
a backside contact structure in direct contact with the bottommost surface of the source drain region and the bottommost surface of the self-aligned backside cap.

18. The semiconductor structure according to claim 15, wherein a lateral width of the self-aligned backside cap is larger than a lateral width of each channel nanosheet in the series of channel nanosheets measured in a direction parallel to the gate structure.

19. The semiconductor structure according to claim 15, wherein a lateral length of the self-aligned backside cap is substantially equal to a lateral length of the gate structure measured in a direction perpendicular to the gate structure.

20. The semiconductor structure according to claim 15, wherein the self-aligned backside cap is laterally offset from a source drain region in a direction perpendicular to the gate structure.
